(19) United States
(12) Patent Application Publication
(10) Pub. No.: US 2023/0043810 A1
(43) Pub. Date: Feb. 9, 2023

(54) III-NITRIDE TRANSISTOR WITH ELECTRICALLY CONNECTED P-TYPE LAYER IN ACCESS REGION

(71) Applicant: Finwave Semiconductor, Inc., Belmont, MA (US)

(72) Inventors: Dongfei Pei, Waban, MA (US); Bin Lu, Fremont, CA (US)

(21) Appl. No.: 17/878,488

(22) Filed: Aug. 1, 2022

Related U.S. Application Data
(60) Provisional application No. 63/229,320, filed on Aug. 4, 2021.

(51) Int. Cl. H01L 29/08; H01L 29/20; H01L 29/205; H01L 29/207; H01L 29/40; H01L 29/778; H01L 29/66

(52) U.S. Cl. CPC H01L 29/0891; H01L 29/2003; H01L 29/205; H01L 29/207; H01L 29/402; H01L 29/7786; H01L 29/66462

(57) ABSTRACT

The structure and technology to improve the device performance of III-nitride semiconductor transistors at high drain voltage when the device is off is disclosed. P-type semiconductor regions are disposed between the gate electrode and the drain contact of the transistor structure. The P-type regions are electrically connected to the drain electrode. In some embodiments, the P-type regions are physically contacting the drain contact. In other embodiments, the P-type regions are physically separate from the drain contact, but electrically connected to the drain contact.

This application claims priority of U.S. Provisional Patent Application Ser. No. 63/229,320, filed Aug. 4, 2021, the disclosure of which is incorporated herein in its entirety.

### FIELD

Embodiments of the present disclosure relate to transistor structures and methods for forming these transistor structures.

### BACKGROUND

Compared with conventional power devices made of silicon, Group III-Nitride (III-N) semiconductors possess excellent electronic properties that enable the fabrication of modern power electronic devices and structures for use in a variety of applications. The limited critical electric field and relatively high resistance of silicon make currently available commercial power devices, circuits and systems constrained with respect to operating frequencies. On the other hand, the higher critical electric field and higher electron density and mobility of III-N materials allow high-current, high-voltage, high-power and/or high-frequency performance of improved power transistors. These attributes are desirable in advanced transportation systems, high-efficiency electricity generation and conversion systems, and energy delivery networks. Such systems rely on efficient power converters to modify electric voltages, and use power transistors capable of blocking large voltages and/or carrying large currents. For example, power transistors with blocking voltages of more than 500V are used in hybrid vehicles to convert DC power from the batteries to AC power. Some other exemplary applications of power transistors include power supplies, automotive electronics, automated factory equipment, motor controls, traction motor drives, high voltage direct current (HVDC) electronics, lamp ballasts, telecommunication circuits and display drives.

Conventional III-nitride semiconductor transistors have a uniform electron density in the access region between the gate and drain electrodes. In the off state, electrons in the drain access region may be depleted to build up a voltage difference between the gate and the drain electrodes. This region is typically covered by a dielectric material.

It would be beneficial if there were a transistor structure with additional p-type semiconductor structures between the gate and drain electrodes that are electrically connected to the drain, which will benefit the device performance at high drain voltage when the device is off.

### SUMMARY

The structure and technology to improve the device performance of III-nitride semiconductor transistors at high drain voltage when the device is off is disclosed. P-type semiconductor regions are disposed between the gate electrode and the drain contact of the transistor structure. The P-type regions are electrically connected to the drain electrode. In some embodiments, the P-type regions are physically contacting the drain contact. In other embodiments, the P-type regions are physically separate from the drain contact, but electrically connected to the drain contact.

According to one embodiment, a semiconductor structure for use in a III-Nitride (III-N) semiconductor device is disclosed. The device comprises a channel layer; a barrier layer, wherein electrons are formed at an interface between the channel layer and the barrier layer; a source contact and a drain contact disposed in ohmic recesses in contact with the barrier layer; a gate electrode disposed between the source contact and the drain contact, wherein a region between the drain contact and the gate electrode comprises a drain access region; and one or more P-type regions disposed in the drain access region, wherein the one or more P-type regions physically contact and are electrically connected to the drain contact. In some embodiments, the one or more P-type regions are made of a p-type semiconductor. In certain embodiments, the p-type semiconductor is p-type GaN. In some embodiments, the p-type GaN is doped with Mg. In some embodiments, a portion of the drain contact is disposed on the one or more P-type regions to create physical contact. In some embodiments, each of the one or more P-type regions has a length (Lp) and a width (Wp), and is separated from an adjacent P-type region by a separation distance (Wo). In some embodiments, the one or more P-type regions are made of a p-type semiconductor and the p-type semiconductor is also disposed between the gate electrode and the barrier layer to form a normally off transistor.

According to a second embodiment, a semiconductor structure for use in a III-Nitride (III-N) semiconductor device is disclosed. The device comprises a channel layer; a barrier layer, wherein electrons are formed at an interface between the channel layer and the barrier layer; a source contact and a drain contact disposed in ohmic recesses in contact with the barrier layer; a gate electrode disposed between the source contact and the drain contact, wherein a region between the drain contact and the gate electrode comprises a drain access region; and one or more P-type regions disposed in the drain access region, wherein the one or more P-type regions are physically separate from and electrically connected to the drain contact. In some embodiments, a dielectric layer is disposed on the one or more P-type regions. In certain embodiments, vias are formed in the dielectric layer and a metal layer is used to electrically connect the one or more P-type regions to the drain contact. In some embodiments, the one or more P-type regions are made of a p-type semiconductor. In certain embodiments, the p-type semiconductor is p-type GaN. In some embodiments, the p-type GaN is doped with Mg. In some embodiments, each of the one or more P-type regions has a length (Lp) and a width (Wp), and is separated from an adjacent P-type region by a separation distance (Wo). In some embodiments, the one or more P-type regions are made of a p-type semiconductor and the p-type semiconductor is also disposed between the gate electrode and the barrier layer to form a normally off transistor.

### BRIEF DESCRIPTION OF THE FIGURES

For a better understanding of the present disclosure, reference is made to the accompanying drawings, which are incorporated herein by reference and in which: FIG. 1A is a top view of a transistor structure according to one embodiment;

FIG. 1B is a cross-section of the transistor structure of FIG. 1A taken along line A-A′;

FIG. 1C is a cross-section of the transistor structure of FIG. 1A taken along line B-B′;

FIG. 1D is a cross-section of the transistor structure of FIG. 1A taken along line C-C′;

FIG. 1E is a cross-section of the transistor structure of FIG. 1A taken along line D-D′;

FIG. 2A is a top view of a transistor structure according to another embodiment;

FIG. 2B is a cross-section of the transistor structure of FIG. 2A taken along line A-A′;

FIG. 2C is a cross-section of the transistor structure of FIG. 2A taken along line B-B′;

FIG. 2D is a cross-section of the transistor structure of FIG. 2A taken along line C-C′;

FIG. 2E is a cross-section of the transistor structure of FIG. 2A taken along line D-D′;

FIG. 3A is a top view of a transistor structure according to a third embodiment;

FIG. 3B is a cross-section of the transistor structure of FIG. 3A taken along line A-A′;

FIG. 3C is a cross-section of the transistor structure of FIG. 3A taken along line B-B′;

FIG. 3D is a cross-section of the transistor structure of FIG. 3A taken along line C-C′;

FIG. 3E is a cross-section of the transistor structure of FIG. 3A taken along line D-D′; and

FIG. 4 shows a flowchart that shows the processes for making the embodiments described herein.

### DETAILED DESCRIPTION

Embodiments of the present disclosure relate to transistor structure with p-type semiconductor structures located between the gate and drain electrode that are electrically connected to the drain electrode. The semiconductor structures described herein may be formed of compound semiconductor materials, such as III-V semiconductor materials, and particularly Group III-Nitride (III-N) semiconductor materials. In each of these embodiments, the drain contacts of III-nitride semiconductor transistors are electrically connected to regions that are P-type semiconductors, also referred to as P-type regions.

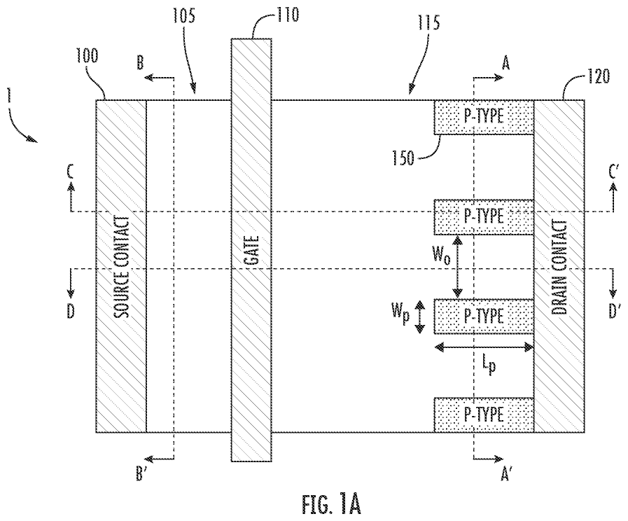

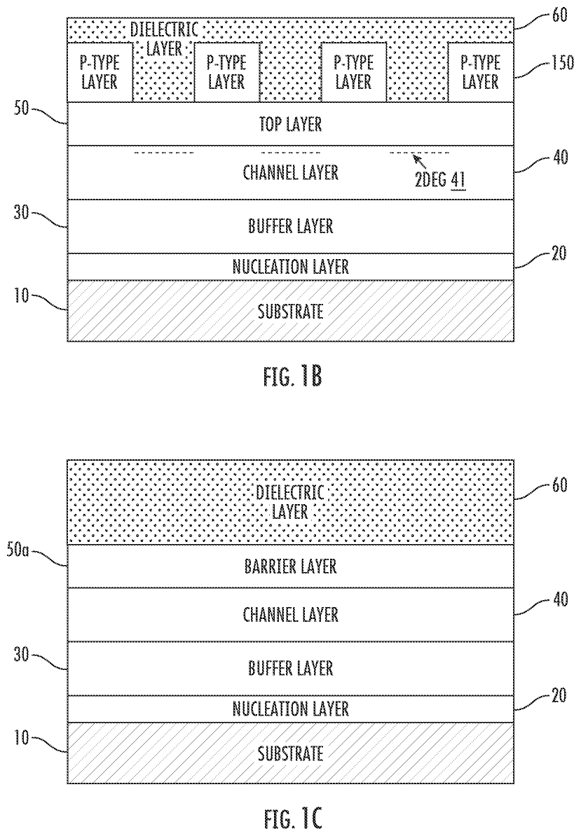

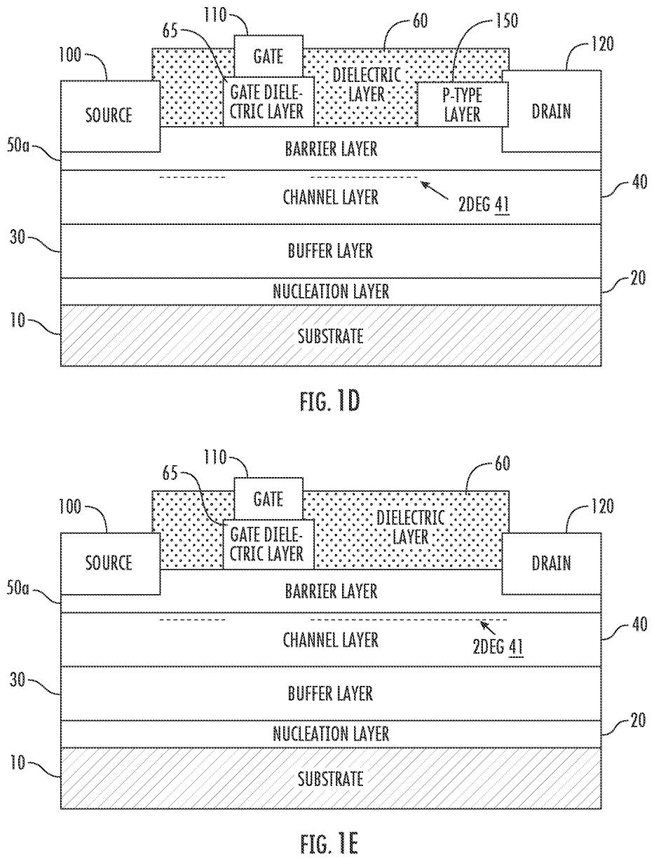

FIG. 1A shows a top view of a transistor structure 1 comprising a source contact 100, a gate electrode 110, and a drain contact 120. A source access region 105 is disposed between the source contact 100 and the gate electrode 110. Additionally, a drain access region 115 is disposed between the gate electrode 110 and the drain contact 120. The source contact 100 may also be an electrode. Similarly, the drain contact 120 may also be an electrode. These electrodes may be made of material selected from titanium, aluminum, titanium nitride, tungsten, tungsten nitride, nickel, gold, copper, platinum, molybdenum, and any other suitable conductive material or combination of conductive materials. The source contact 100 and the drain contact 120 form ohmic contacts to the barrier layer 50a (see FIGS. 1D and 1E).

As shown in FIG. 1A, one or more P-type regions 150 are shown. These P-type regions 150 are electrically connected to the drain contact 120. The 2-dimensional electron gas (2DEG) under the P-type regions 150 is either depleted or reduced, as compared to other areas of the drain access region 115.

In one embodiment, these P-type regions 150 may have a length of Lp, a width of Wp and separation distance of Wo in the width direction. In this disclosure, length is defined as the direction from the source contact 100 to the drain contact 120. Width is the direction perpendicular to the length. The length of the P-type regions 150 may be between 50 and 5000 nm. The width of the P-type regions may also be between 50 and 5000 nm. In other embodiments, the P-type regions 150 may be different shapes and/or may be non-periodic distributed. Further, the P-type regions 150 are located between the gate electrode 110 and the drain contact 120 in the drain access region 115. The p-type region 150 should not occupy all the width of the drain access region 115. The p-type regions 150 may have a thickness of between 10 and 200 nm, although other thicknesses are also possible.

FIG. 1B shows the cross-section of the III-nitride semiconductor transistor structure 1 along the cutline A-A′. FIG. 1C shows the cross-section of the III-nitride semiconductor transistor structure 1 along the cutline B-B′.

The transistor structure 1 comprises a substrate 10, which may be made of Si, SiC, Sapphire, III-nitride semiconductor or any other suitable material.

In some embodiments, the semiconductor transistor structure 1 may include a nucleation layer 20, formed on the substrate 10. The nucleation layer 20 may include AlN.

A buffer layer 30 is formed over the nucleation layer 20. The buffer layer 30 may have a thickness between 0.5 nm and several microns. A channel layer 40 is formed over the buffer layer 30. The buffer layer 30 and channel layer 40 comprise III-nitride semiconductors including GaN, AlGaN, InGaN, InAlN, InAlGaN and AlN. Free electrons 41 exist in the channel layer 40 to conduct electrical current between the drain contact 120 and the source contact 100. The channel layer 40 may comprise a single layer such as a GaN layer, or multiple layers. In one example, the channel layer 40 comprises a back-barrier structure, such as a GaN layer over an AlGaN layer (GaN/AlGaN) or a GaN layer over an InGaN layer and another GaN layer (GaN/InGaN/GaN). In another example, the channel layer 40 has a superlattice structure formed by repeating a bi-layer structure of AlGaN/GaN or AlN/GaN. The thickness of the channel layer 40 may be 5 nm, although other thicknesses may be used. The thickness of the buffer layer 30 may be between zero and a few microns, although other thicknesses are within the scope of the disclosure.

A top layer 50 is formed over the channel layer 40. The top layer 50 includes a barrier layer 50a, which is made of III-nitride semiconductors selected from AlGaN, InAlN, AlN or InAlGaN. The top layer 50 is formed on the channel layer 40. The top layer 50 may have other sub-layers such as etch stop layers, spacer layers and/or a cap layer made of III-nitride semiconductors including GaN, AlN, AlGaN, InGaN, and InAlGaN. The barrier layer 50a may be un-doped, doped with Si or doped with Mg or other impurities.

In one embodiment of the transistor structure 1, the AlGaN barrier layer 50a is formed over channel layer 40 comprising GaN. Free electrons 41 are formed at the interface between the AlGaN barrier layer 50a and the GaN channel layer 40. Specifically, electrons 41 are formed as a two dimensional electron gas (2DEG) at the interface between the channel layer 40 and the barrier layer 50a.

In some embodiments, a dielectric layer 60 is disposed on top of the top layer 50. The dielectric layer 60 is made of dielectric material such as SiO₂, SiₓN_{y}, SiOₓN_{y}, Al₂O₃, HfO₂ and any other suitable dielectric material.

The III-nitride semiconductor transistor 1 shown in FIG. 1D may be a normally-on transistor with free electrons 41 underneath the gate electrode 110 without any applied gate voltage or a normally-off transistor without free electrons 41 underneath the gate electrode 110 without any applied gate voltage. In another embodiment, the III-nitride semiconductor transistor 1 may be a normally-off transistor. In that embodiment, the normally-off transistor may have a recessed region in the barrier layer 50a underneath the gate electrode 110 or a Mg-doped III-nitride layer underneath the gate electrode 110.

FIG. 1D shows the cross-section of the III-nitride semiconductor transistor structure 1 along the cutline C-C′. FIG. 1E shows the cross-section of the III-nitride semiconductor transistor structure 1 along the cutline D-D′. As shown in FIGS. 1D and 1E, the gate electrode 110 is formed over the top layer 50. There may be a gate dielectric layer 65 between the gate electrode 110 and the barrier layer 50a. The gate dielectric layer 65 may be selected from material including SiO₂, SiₓN_{y}, SiOₓN_{y}, Al₂O₃, HfO₂ and any other suitable dielectric material. In another embodiment, to create a normally-off transistor, the gate dielectric layer 65 is not present and the gate electrode 110 may make electrical contact to the barrier layer 50a directly forming a Schottky contact or ohmic contact. In another embodiment, the gate dielectric layer 65 may be replaced with a Mg-doped III-nitride layer to create a normally-off transistor.

The source contact 100 and the drain contact 120 may be formed by ohmic metal contact with the barrier layer with or without a recess in the barrier layer 50a in the ohmic region. The material of the gate electrode 110, the source contact 100 and the drain contact 120 is selected from Ni, Au, Ti, Al, TiN, W, WN, Pt, Cu, Mo and any other suitable material and their combination.

The III-nitride semiconductor transistor structure may be formed with Gallium-face or Nitrogen-face III-nitride semiconductors.

The p-type layer 150 is formed in the drain access region 115, which is the region between the gate electrode 110 and drain contact 120. The p-type layer 150 is made of III-nitride semiconductors including GaN, AlGaN, InGaN, InAlGaN. The p-type layer 150 is sufficiently doped with Mg or other impurities so that the layer becomes a p-type semiconductor. In one embodiment, shown in FIGS. 1A and 1D, the p-type layer 150 can be directly overlapped with the drain contact 120 to create a metal-semiconductor contact. In other words, in this embodiment, the P-type regions 150 physically contact the drain contact 120. In this way, the P-type regions 150 are electrically connected to the drain contact 120. In one embodiment, the drain contact 120 is added after the P-type regions 150 such that a portion of the drain contact 120 is disposed on top of part of the P-type regions 150.

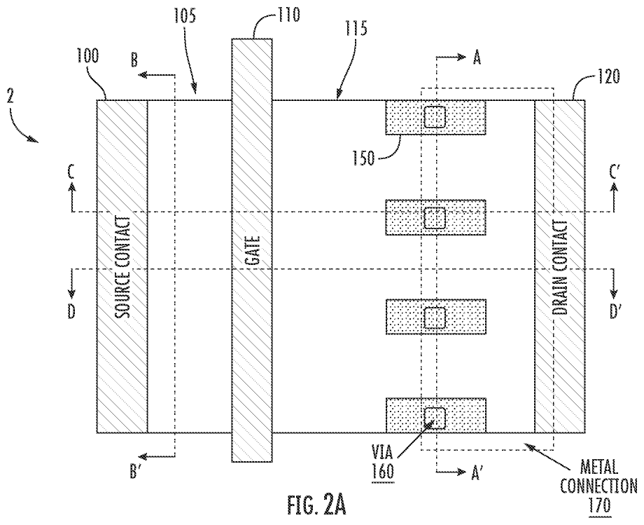

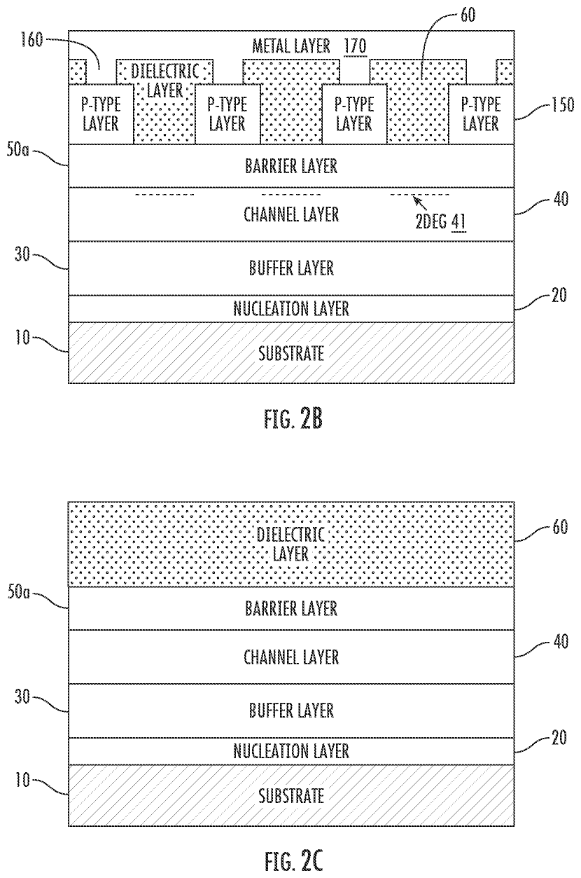

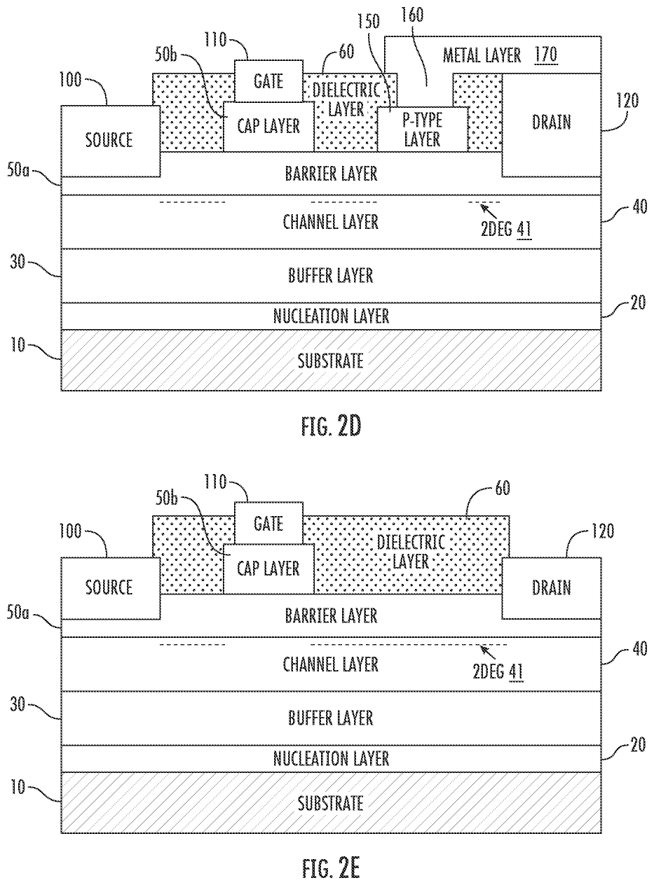

FIGS. 2A-2E show a second embodiment of the transistor structure 2. Components with the same function have been given the identical reference designators. In this embodiment, the P-type regions 150 are physically separate from the drain contact 120. In this embodiment, the transistor structure 2 shown in FIG. 2D is a normally-off transistor.

FIG. 2A shows a top view of a transistor structure 2 comprising a source contact 100, a gate electrode 110, and a drain contact 120. FIG. 2B shows the cross-section of the III-nitride semiconductor transistor structure 2 along the cutline A-A′. FIG. 2C shows the cross-section of the III-nitride semiconductor transistor structure 2 along the cutline B-B′. FIG. 2D shows the cross-section of the III-nitride semiconductor transistor structure 2 along the cutline C-C′. FIG. 2E shows the cross-section of the III-nitride semiconductor transistor structure 2 along the cutline D-D′.

As seen in FIG. 2B, the p-type layer 150 is covered with a dielectric layer 60. The dielectric layer 60 is made of dielectric material such as SiO₂, SiₓN_{y}, SiOₓN_{y}, Al₂O₃, HfO₂ and any other suitable dielectric material. The dielectric layer 60 is etched over the top of the p-type layer 150 to create a via 160. As seen in FIG. 2D, an electrical connection is formed to connect the p-type layers 150 to one another and to the drain contact 120. This electrical connection may be metal layer 170. The material of the electrical connection is selected from Ni, Au, Ti, Al, TiN, W, WN, Pt, Cu, Mo and any other suitable material and their combination. This metal layer 170 can be formed together with the gate electrode 110 or separately. As seen in FIG. 2D, a cap layer 50b is disposed between the gate electrode 110 and the barrier layer 50a. The cap layer 50b may be made of III-nitride semiconductors including GaN, AlN, AlGaN, InGaN, and InAlGaN. The cap layer 50b may be p-doped. In some embodiments, the cap layer 50b is p-doped GaN, but other III-V materials may be used as well.

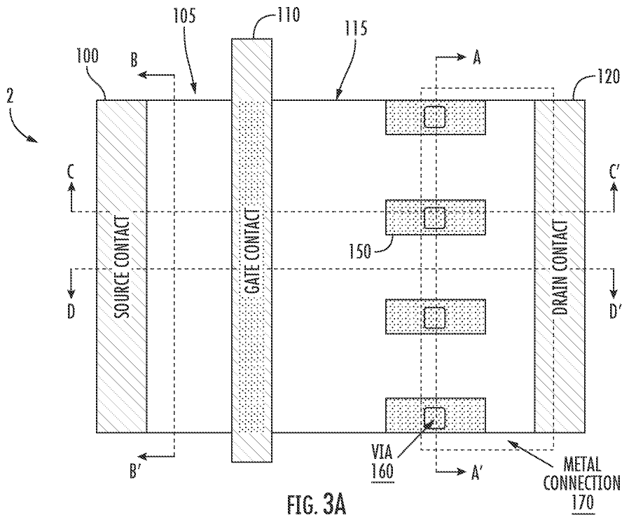

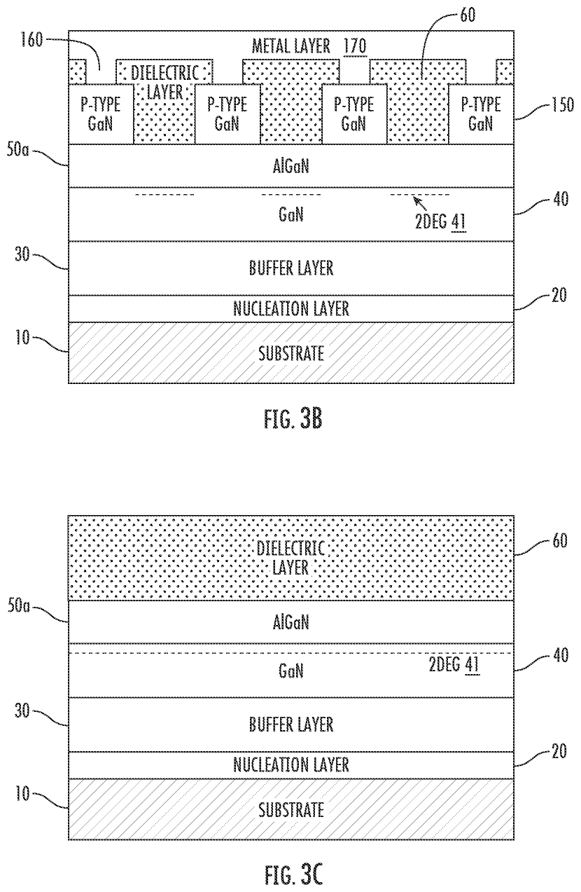

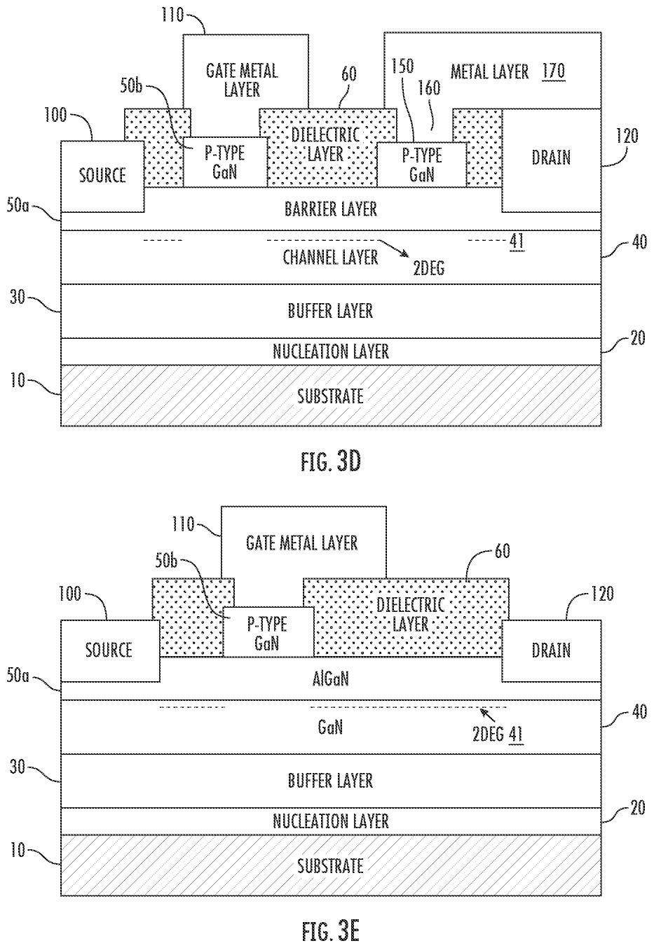

FIG. 3A shows a top view of a transistor structure 3 comprising a source contact 100, a gate electrode 110, and a drain contact 120. FIG. 3B shows the cross-section of the III-nitride semiconductor transistor structure 3 along the cutline A-A′. FIG. 3C shows the cross-section of the III-nitride semiconductor transistor structure 2 along the cutline B-B′. FIG. 3D shows the cross-section of the III-nitride semiconductor transistor structure 2 along the cutline C-C′. FIG. 3E shows the cross-section of the III-nitride semiconductor transistor structure 2 along the cutline D-D′.

This embodiment is very similar to that shown in FIGS. 2A-2E. In this embodiment, the channel layer 40 is GaN, and the barrier layer 50a is AlGaN. Further, the P-type regions 150 are a P-type GaN. The transistor is a normally off transistor with p-type GaN layer under the gate electrode 110. Note that, as shown in FIG. 3D, the cap layer 50b is the same material as the P-type regions 150. Thus, in this embodiment, the P-type regions 150 and the cap layer 50b may be grown at the same time. In other words, P-type GaN is formed in the gate area between the source contact 100 and drain contact 120. Rectangles of p-type GaN (i.e., P-type regions 150) are formed in the drain access region 115. Dielectric layers are formed over the p-type GaN regions 150 and the exposed barrier layer 50a.

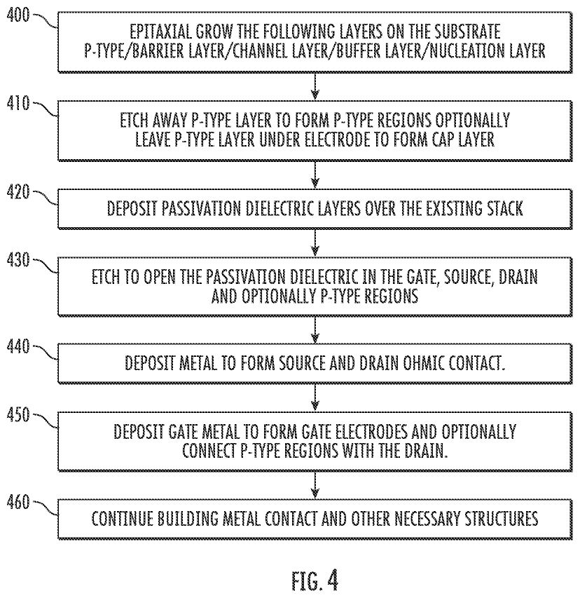

An example of fabricating the transistor structure described in FIGS. 3A-3E is shown in FIG. 4. First, as shown in Box 400, a substrate 10 is provided. A nucleation layer 20 is epitaxially grown on top of the substrate and a buffer layer 30 is grown on the nucleation layer 20. A channel layer 40 is then epitaxially grown on the buffer layer 30 and a top layer 50 is grown on the channel layer 40. Further, a P-type GaN layer is epitaxially grown on the top layer 50.

Next, as shown in Box 410, the P-type regions 150 are formed on the wafer. This may be accomplished by etching the P-type layer to create the P-type regions 150. In certain embodiments, the P-type layer is not etched in the gate region. Thus, in these embodiments, the cap layer 50b is the same material as the P-type regions 150. This is done to create a normally-off transistor. In other embodiments, the P-type layer is etched so that only P-type regions 150 remain. This allows the formation of a normally-on transistor.

After the P-type regions 150 have been formed, a dielectric layer 60 is then deposited over the entire substrate, as shown in Box 420. The dielectric layer 60 may be deposited on the entirety of the barrier layer 50a and the P-type regions 150. Thus, the dielectric layer 60 coats the barrier layer 50a and the P-type regions 150 in the source access region 105, and the drain access region 115.

Openings are then etched into the dielectric layer 60, as shown in Box 430. These opening are in the positions needed for the gate electrode 110, the source contact 100 and the drain contact 120. In the embodiments shown in FIGS. 2A-2E and 3A-3E, openings are also created above the P-type regions 150 to form vias 160. Note that these vias 160 are not necessary in the embodiment of FIG. 1A-1E, since the P-type regions 150 physically contact the drain contact 120.

As shown in Box 440, source contact 100 and drain contact 120 are formed in these ohmic recesses. In some embodiments, the source contact 100 and drain contact 120 are formed by metal layers contacting the AlGaN barrier layer. In the embodiment shown in FIGS. 1A-1E, the drain contact 120 is formed such that it physically contacts the P-type regions 150. Optionally, a portion of the drain contact 120 may overlap a portion of the P-type regions 150 to ensure physical contact.

Next, as shown in Box 450, the gate electrode 110 is formed between the source contact 100 and the drain contact 120. Additionally, in the embodiments shown in FIGS. 2A-2E and 3A-3E, metal is deposited on top of the dielectric layer 60 to form the metal layer 170 which enters the vias 160 and electrically connects the P-type regions 150 to the drain contact 120.

The sequence of forming the gate electrode 110, the source contact 100 and drain contact 120 may be changed. For example, gate electrode 110 may be formed before deposition of dielectric layer 180. Source contact 100 and drain contact 120 may be formed after the formation of the gate electrode 110.

Finally, as shown in Box 460, building metal and other structures may be added to the substrate.

Additional process steps not shown in FIG. 4 include depositing additional dielectric layers, and forming additional field plates, vias and interconnections.

The transistor of this disclosure may contain other structures such as field plate electrodes, metal interconnects, top isolation dielectrics and other structures.

Additionally, the P-type regions of FIG. 1A-1E and those of FIGS. 2A-2E may be combined such that there are some P-type regions 150 that physically touch the drain contact, and others that are physically separated and are connected using a metal layer 170.

Thus, the P-type regions 150 are disposed in the drain access region 115 and are in electrical contact with the drain contact 120. Further, the width of the P-type regions 150 may be less than the width of the drain access region 115 or the drain contacts 120. Further, the length of the P-type regions 150 is such that the P-type regions 150 do not extend to the gate electrode 110.

The embodiments described above in the present application may have many advantages. The P-type regions 150 enables a leakage path between the drain access region and the drain electrode. At very high drain voltage while the gate is turned off, the leakage path may protect the device from permanent breakdown.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor structure for use in a III-Nitride (III-N) semiconductor device, comprising:
a channel layer;
a barrier layer, wherein electrons are formed at an interface between the channel layer and the barrier layer;
a source contact and a drain contact disposed in ohmic recesses in contact with the barrier layer;
a gate electrode disposed between the source contact and the drain contact, wherein a region between the drain contact and the gate electrode comprises a drain access region; and
one or more P-type regions disposed in the drain access region, wherein the one or more P-type regions physically contact and are electrically connected to the drain contact.

2. The semiconductor structure of claim 1, wherein the one or more P-type regions are made of a p-type semiconductor.

3. The semiconductor structure of claim 2, wherein the p-type semiconductor is p-type GaN.

4. The semiconductor structure of claim 3, wherein the p-type GaN is doped with Mg.

5. The semiconductor structure of claim 1, wherein a portion of the drain contact is disposed on the one or more P-type regions to create physical contact.

6. The semiconductor structure of claim 1, wherein each of the one or more P-type regions has a length (Lp) and a width (Wp), and is separated from an adjacent P-type region by a separation distance (Wo).

7. The semiconductor structure of claim 1, wherein the one or more P-type regions are made of a p-type semiconductor and wherein the p-type semiconductor is also disposed between the gate electrode and the barrier layer to form a normally off transistor.

8. A semiconductor structure for use in a III-Nitride (III-N) semiconductor device, comprising:
a channel layer;
a barrier layer, wherein electrons are formed at an interface between the channel layer and the barrier layer;
a source contact and a drain contact disposed in ohmic recesses in contact with the barrier layer;
a gate electrode disposed between the source contact and the drain contact, wherein a region between the drain contact and the gate electrode comprises a drain access region; and
one or more P-type regions disposed in the drain access region, wherein the one or more P-type regions are physically separate from and electrically connected to the drain contact.

9. The semiconductor structure of claim 8, wherein a dielectric layer is disposed on the one or more P-type regions.

10. The semiconductor structure of claim 9, wherein vias are formed in the dielectric layer and a metal layer is used to electrically connect the one or more P-type regions to the drain contact.

11. The semiconductor structure of claim 8, wherein the one or more P-type regions are made of a p-type semiconductor.

12. The semiconductor structure of claim 11, wherein the p-type semiconductor is p-type GaN.

13. The semiconductor structure of claim 12, wherein the p-type GaN is doped with Mg.

14. The semiconductor structure of claim 8, wherein each of the one or more P-type regions has a length (Lp) and a width (Wp), and is separated from an adjacent P-type region by a separation distance (Wo).

15. The semiconductor structure of claim 8, wherein the one or more P-type regions are made of a p-type semiconductor and wherein the p-type semiconductor is also disposed between the gate electrode and the barrier layer to form a normally off transistor.
